(19) United States
(12) Patent Application Publication
(10) Pub. No.: US 2019/0236731 A1
(43) Pub. Date: Aug. 1, 2019

(54) METHOD FOR DETERMINING AN ENERGY EFFICIENCY OF A PIECE OF REAL ESTATE

(71) Applicant: Grohe AG, Hemer (DE)

(72) Inventors: Torsten MEIER, Neuss (DE); Bert DEPIERE, Wakkerzeel (BE)

(73) Assignee: Grohe AG, Hemer (DE)

(21) Appl. No.: 16/260,880

(22) Filed: Jan. 29, 2019

(30) Foreign Application Priority Data
Jan. 29, 2018 (DE) 10 2018 000 669.8

(51) Int. Cl. G06Q 50/16; G06Q 50/06; G01R 21/14

(52) U.S. Cl. CPC G06Q 50/163; G01R 21/14; G06Q 50/06

(57) ABSTRACT

A method for determining an energy efficiency of a piece of real estate, which includes: determining a volume flow and a first temperature of a heat transfer medium, which flows from at least one heating device to at least one heat transfer device; determining at least one second temperature in the piece of real estate with the aid of at least one temperature sensor; and calculating an energy efficiency of the piece of real estate based on the volume flow, the first temperature and the second temperature.

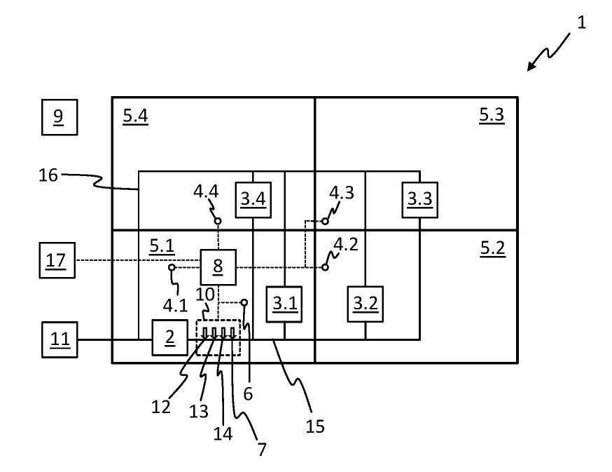

This nonprovisional application claims priority under 35 U.S.C. § 119(a) to German Patent Application No. 10 2018 000 669.8, which was filed in Germany on Jan. 29, 2018, and which is herein incorporated by reference.

### BACKGROUND OF THE INVENTION

### Field of the Invention

The present invention relates to a method for determining an energy efficiency of a piece of real estate, with the aid of which energy performance values of the piece of real estate may be monitored.

### Description of the Background Art

In some countries, the maximum energy demand values for real estate and a calculation of the particular energy demand values for real estate are stipulated. The energy demand values calculated for a piece of real estate are recorded, for example, in an energy performance certificate, which must be presented in a change of tenant or a change of owner in order to disclose the energy demand of the piece of real estate and thus the energy costs to be expected. The calculation rules for the energy evaluation of the real estate are also regularly stipulated and are based, among other things, on an energy evaluation of the property shell as well as that of the technical installations used, in particular the heating system. However, it has been proven that the actual energy demand of the piece of real estate frequently deviates from the calculated energy demand, so that unexpectedly high energy costs may arise.

### SUMMARY OF THE INVENTION

It is therefore an object of the present invention to therefore to at least partially solve the problems described with respect to the prior art and, in particular, to specify a method for determining the energy efficiency of a piece of real estate, with the aid of which the energy demand of the piece of real estate may be monitored.

A method for determining an energy efficiency of a piece of real estate contributes hereto, which can comprise at least the following steps: (a) determining a volume flow and a first temperature of a heat transfer medium, which flows from at least one heating device to at least one heat transfer device; (b) determining at least one second temperature in the piece of real estate with the aid of at least one temperature sensor; and (c) calculating an energy efficiency of the piece of real estate based on the volume flow, the first temperature and the second temperature.

The energy efficiency of a piece of real estate is, in particular, a ratio between energy output and energy input. Energy efficiency is thus understood to be the most sparing or economical use of energy and energy input, losses which occur, for example, during the conversion, transport and/or storage of the energy, being able to be minimized. The piece of real estate may be, for example, a residential building, an industrial building, a floor of a building, an apartment or a hotel room.

In step a), a volume flow and a first temperature of a heat transfer medium are determined, the heat transfer medium flowing from at least one heating device to at least one heat transfer device. The heating device is, in particular, an appliance for heating the piece of real estate, for example in the manner of a central heating system, or for heating individual rooms of the real estate, for example in the manner of an individual heater. In particular, the heating device may be a gas heater, oil heater, pellet heater, wood heater, electric heater or heat pump heater. The heating device heats the fluid heat transfer medium, which is subsequently supplied to the at least one heat transfer device via at least one heating circuit line, in particular with the aid of an (electric) pump. The heat transfer medium is, in particular, water and/or, in the case of the at least one heating circuit line, at least one pipeline, which is, for example, at least partially made from metal, such as copper or a copper alloy. The at least one heating circuit line may have, in particular a diameter of 10 mm (millimeters) to 80 mm. The at least one heat transfer device may be, for example, a radiator, in particular in the manner of a heating element, or a space heating system, in particular in the manner of a floor heater or a wall heater. After reaching the at least one heat transfer device, the heat transfer medium is fed back, in particular, to the at least one heating device, where it is reheated by the at least one heating device. The heat transfer medium is thus guided, in particular, through a heat circuit. The at least one heat transfer device is used, in particular, to heat a room air in the piece of real estate.

The volume flow and the first temperature of the heat transfer medium are determined, in particular, (directly) after leaving the at least one heating device, for example downstream along the heating circuit line at a distance of less that 5 m (meters), preferably less than 2.5 m and particularly preferably less than 1 m from the at least one heating device. The first temperature is, in particular, an inlet temperature of the heat transfer medium. A measuring device, which comprises a flow sensor and a temperature sensor, may be used to determine the volume flow and the first temperature of the heat transfer medium. The measuring device may be combined with a shutoff valve and/or a water meter for the heating circuit line.

In step b), at least one second temperature in the piece of real estate is determined with the aid of at least one temperature sensor. With the aid of the at least one temperature sensor, it thus possible to determine, in particular, how much of the thermal energy generated by the at least one heating device is actually used in the piece of real estate and how much loss of generated thermal energy occurs.

In step c), an energy efficiency of the piece of real estate is calculated based on or as a function of the volume flow, the first temperature and the second temperature. The result may be displayed to a resident of the piece of real estate, for example continuously via a display. The result may also be sent to a cloud device, which may be, in particular, a server outside the piece of real estate. The energy efficiency of the piece of real estate may furthermore be queried via the cloud device, for example with the aid of a smart phone. If the energy efficiency of the piece of real estate drops below a predefinable threshold value, the resident of the piece of real estate may be warned, for example with the aid of a push notification on the smart phone. The resident may thereby end a possibly energy-inefficient behavior, for example due to excessively long ventilation, and thus again increase the energy efficiency of the piece of real estate as well as reduce a CO² emission of the at least one heating device. Unexpectedly high energy costs may thus also be avoided.

Moreover, the calculation of the energy efficiency in step c) may additionally take place on the basis of an outdoor temperature. The outdoor temperature is a temperature which prevails, in particular, in the immediate surroundings of the piece of real estate outside the piece of real estate. The outdoor temperature may be determined, for example with the aid of at least one outdoor temperature sensor. In the proposed method, the energy introduced into the piece of real estate is thus determined in step a); a temperature characteristic in the piece of real estate or in individual rooms of the piece of real estate is determined in step b); and a conclusion as to the energy efficiency of the piece of real estate is drawn via the outdoor temperature in step c), in particular from real-time data.

Moreover, the outdoor temperature may be queried from an Internet platform. The query takes place, in particular, over the Internet and/or for a location of the piece of real estate. The Internet platform is, in particular, a website, on which weather data, for example outdoor temperatures, are regularly published, i.e. in particular daily and/or hourly.

The air temperature in the piece of real estate may furthermore be determined in step b). For this purpose, the at least one temperature sensor may be fixedly or movably disposed, for example in or on the at least one heat transfer device, a floor and/or a doorstop.

The air temperature in all rooms of the piece of real estate may also be determined. For this purpose, at least one temperature sensor may be disposed in each room of the piece of real estate.

A humidity in the piece of real estate may furthermore be determined with the aid of at least one humidity sensor.

A vibration may also be measured with the aid of at least one vibration sensor.

In addition, at least one of the following parameters may be taken into account in the calculation in step c):
Size of the piece of real estate, in particular its floor space and/or volume;
Number of rooms of the piece of real estate;
Insulation of the piece of real estate, in particular of the walls facing the outer surroundings of the piece of real estate;
Power output of the at least one heating device.

The calculation in step c) may furthermore take place with the aid of a controller. The controller comprises, in particular, at least one microcontroller. The controller is also connected, in particular data-conductively, to the measuring device, the flow sensor and the at least one temperature sensor, for example with the aid of a cable connection and/or a wireless connection. The controller may also be data-conductively connected to the at least one outdoor temperature sensor with the aid of a cable connection and/or a wireless connection. It is preferred that all components above belong to an inter-communicating network.

The calculation in step c) may furthermore take place with the aid of a cloud device. The controller may be provided, for example, in the cloud device. Alternatively, the controller may be connected to the cloud device, for example via a network router and an Internet connection.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWING

The present invention will become more fully understood from the detailed description given hereinbelow and the accompanying drawings which are given by way of illustration only, and thus, are not limitive of the present invention, and wherein: the sole FIGURE schematically shows a piece of real estate, including a heating device, by way of example.

### DETAILED DESCRIPTION

The FIGURE shows a schematic view of a piece of real estate 1, including a heating device 2. Heating device 2 is connected via a large number of heating circuit lines 15 to a large number of heat transfer devices 3.1 through 3.4, which are each situated in a room 5.1 through 5.4 of piece of real estate 1. A heat transfer medium may be heated by heating device 2 and supplied to heat transfer devices 3.1 through 3.4 via heating circuit lines 15, so that heat transfer device 3.1 through 3.4 may heat a room air in rooms 5.1 through 5.4. The at least partially cooled heat transfer medium is subsequently fed back to heating device 2 via additional heating circuit lines 15. A heating circuit 16 is thus formed in piece of real estate 1 by heating circuit lines 15. The heat transfer medium may be supplied to heating circuit 16 via a fluid source 11, for example a public water supply network, if losses of the heat transfer medium occur in heating circuit 16, for example due to leaks. A measuring device 10, comprising a first temperature sensor 12, a flow sensor 13, a pressure sensor 14 and a vibration sensor 7, is disposed directly downstream from heating device 2. A temperature of the heat transfer medium in heating circuit line 15 may be determined with the aid of first temperature sensor 12, a volume flow of the heat transfer medium flowing through heating circuit line 15 may be determined with the aid of flow sensor 13, and a pressure of the heat transfer medium flowing through heating circuit line 15 may be determined with the aid of pressure sensor 14. Vibrations at heating circuit lines 15 may also be measured with the aid of vibration sensor 7. Measuring device 10 is data-conductively connected to a controller 8 for transmitting the measured values measured by the sensors. Controller 8 is also data-conductively connected to second temperature sensors 4.1 through 4.4 situated in individual rooms 5.1 through 5.4 for determining an air temperature in individual rooms 5.1 through 5.4 as well as to humidity sensors 6 situated in room 5.1 for determining a humidity in room 5.1. It should be noted that a humidity sensor 6 may be disposed in each room 5.1 through 5.4. Controller 8 is furthermore connected to an outdoor temperature sensor 17, with the aid of which an outdoor temperature may be determined. Outdoor temperature sensor 17 is also data-conductively connected to controller 8. An energy efficiency of piece of real estate 1 may thus be calculated with the aid of controller 8. Controller 8 may be situated in piece of real estate 1 and/or be provided in a cloud device 9.

The energy demand of the piece of real estate may be monitored continuously by the present invention.

The invention being thus described, it will be obvious that the same may be varied in many ways. Such variations are not to be regarded as a departure from the spirit and scope of the invention, and all such modifications as would be obvious to one skilled in the art are to be included within the scope of the following claims

What is claimed is:

1. A method for determining an energy efficiency of a piece of real estate, the method comprising:
determining a volume flow and a first temperature of a heat transfer medium, which flows from at least one heating device to at least one heat transfer device;
determining at least one second temperature in the piece of real estate with the aid of at least one temperature sensor; and
calculating an energy efficiency of the piece of real estate based on the volume flow, the first temperature and the second temperature.

2. The method according to claim 1, wherein the calculation of the energy efficiency additionally takes place on the basis of an outdoor temperature.

3. The method according to claim 2, wherein the outdoor temperature is queried from an Internet platform.

4. The method according to claim 1, wherein the air temperature in the piece of real estate is determined in the step of determining at least one second temperature.

5. The method according to claim 4, wherein the air temperature in all rooms of the piece of real estate is determined.

6. The method according to claim 1, wherein a humidity in the piece of real estate is determined with the aid of at least one humidity sensor.

7. The method according to claim 1, wherein a vibration is measured with the aid of at least one vibration sensor.

8. The method according to claim 1, wherein at least one of the following parameters is taken into account in the calculation of energy efficiency:
size of the piece of real estate;
number of rooms of the piece of real estate;
number of rooms having at least one temperature sensor;
insulation of the piece of real estate; and/or
power output of the at least one heating device.

9. The method according to claim 1, wherein the calculation takes place with the aid of a controller.

10. The method according to claim 1, wherein the calculation takes place with the aid of a cloud device.
